(19) United States
(12) Patent Application Publication
(10) Pub. No.: US 2007/0209592 A1
(43) Pub. Date: Sep. 13, 2007

(54) LOW-PRESSURE PROCESS APPARATUS

(75) Inventor: Ting-Hui Huang, Tao Yuan Shien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: QUANTA DISPLAY INC., Tao Yuan Shien (TW)

(21) Appl. No.: 11/609,537

(22) Filed: Dec. 12, 2006

(30) Foreign Application Priority Data
Mar. 10, 2006 (TW) 95108134

(51) Int. Cl. C23C 16/00; B03C 7/00

(52) U.S. Cl. 118/722; 118/726; 209/127.1

(57) ABSTRACT

A low-pressure process apparatus for processing a substrate includes a chamber, a carrier and an exhaust module. The carrier is disposed in the chamber supporting the substrate. The exhaust module includes a first exhaust unit and a second exhaust unit. The first exhaust unit includes a plurality of first exhaust openings. The second exhaust unit includes a plurality of second exhaust openings. The second exhaust openings surround the first exhaust openings. The first and second exhaust openings are located in the chamber, and air in the chamber is exhausted through the first and second exhaust openings at substantially the same exhaust pressure, thereby decreasing air pressure therein.

### BACKGROUND OF THE INVENTION

1. Field of the Invention

The invention relates to a low-pressure process apparatus, and in particular to a low-pressure process apparatus for large substrates.

2. Description of the Related Art

FIG. 1a shows a conventional low-pressure process apparatus 10 comprising a base 11, a stage 12, a housing 14 and an exhaust pipe 15. The stage 12 is disposed on the base 11. A chamber 16 is constructed of the housing 14 and the stage 12. A substrate 13 is located on the stage 12 in the chamber 16. The housing 14 comprises an exhaust opening 17 communicating with the exhaust pipe 15 to remove air from the chamber 16, decreasing air pressure therein.

When photoresist material (for example, resin film) on the substrate 13 (particularly a large substrate) is dried in conventional low-pressure process apparatus 10, air in the chamber 16 is exhausted only through the exhaust opening 17, venting flow thus generated therein, and uniformity of the photoresist material is decreased. Additionally, when the vacuum state of the chamber 16 is broken, particles can enter and pollute the chamber 16.

FIG. 1b shows another conventional low-pressure process apparatus 20 comprising a base 21, a stage 22, a housing 24, an exhaust pipe 25 and a carrier 27. The stage 22 is disposed on the base 21. A chamber 26 is constructed of the housing 24 and the stage 22. The carrier 27 is disposed on the stage 22 with exhaust openings 28 disposed on sidewalls thereof. The substrate 13 is disposed on the carrier 27 in the chamber 26. The exhaust pipe 25 is communicating with the exhaust openings 28 to remove air from the chamber 26, decreasing air pressure therein.

The exhaust openings 28 are below the substrate 13, complicating the airflow path. When photoresist material (for example, resin film) on the substrate 13 (particularly a large substrate) is dried in conventional low-pressure process apparatus 20, turbulence is generated, and uniformity of the photoresist material is decreased. When the vacuum state of the chamber 26 is broken, particles can enter and pollute the chamber 26. Additionally, since the exhaust openings 28 are near the substrate 13, the substrate 13 is curved by the strong air pressure around the exhaust openings 28, and the uniformity of the photoresist material is deteriorated.

### BRIEF SUMMARY OF THE INVENTION

A detailed description is given in the following embodiments with reference to the accompanying drawings.

The invention provides a low-pressure process apparatus for processing a substrate comprising a chamber, a carrier and an exhaust module. The carrier is disposed in the chamber for supporting the substrate. The exhaust module comprises a first exhaust unit and a second exhaust unit. The first exhaust unit comprises a plurality of first exhaust openings. The second exhaust unit comprises a plurality of second exhaust openings. The second exhaust openings surround the first exhaust openings. The first and second exhaust openings are located in the chamber, and air in the chamber is exhausted through the first and second exhaust openings at the same exhaust pressure, decreasing air pressure therein.

In one embodiment of the invention, the exhaust module removes the air from the chamber in a vertical direction.

In one embodiment of the invention, the first and the second exhaust openings are arranged in a matrix.

The invention provides another low-pressure process apparatus for processing a substrate, which comprises a chamber, a carrier and an exhaust module. The carrier is disposed in the chamber for supporting the substrate. The exhaust module comprises a plurality of exhaust openings and a plurality of particle gathering elements. The exhaust openings are located in the chamber above the carrier, wherein air in the chamber is exhausted through the exhaust openings, decreasing air pressure therein, with each particle gathering element disposed below each exhaust opening.

In one embodiment of the invention, each particle gathering element comprises a concave corresponding to the exhaust opening.

In one embodiment of the invention, each particle gathering element further comprises fluid guiding portions opposite to the concave having curved surfaces.

When the low-pressure process apparatus performs a pressure reducing process, air exhaust pressure in the chamber is uniform, and venting flow is prevented from generating. Additionally, the low-pressure process apparatus can uniformly dry a photoresist material on a substrate.

### BRIEF DESCRIPTION OF THE DRAWINGS

The invention can be more fully understood by reading the subsequent detailed description and examples with references made to the accompanying drawings, where:

FIG. 1a shows a conventional low-pressure process apparatus;

FIG. 1b shows another conventional low-pressure process apparatus;

FIG. 2 is a front view of a low-pressure process apparatus of the invention;

FIG. 3a is a top view of the low-pressure process apparatus;

FIG. 3b shows a first exhaust unit of the low-pressure process apparatus, according to the present invention;

FIG. 3c shows a second exhaust unit of the low-pressure process apparatus, according to the present invention;

FIG. 3d shows a third exhaust unit of the low-pressure process apparatus, according to the present invention;

FIG. 4 is a side view of the low-pressure process apparatus, according to the present invention;

FIG. 5 shows the pressure reducing process of the low-pressure process apparatus, according to the present invention;

FIG. 6a shows the low-pressure process apparatus comprising a heater, according to the present invention;

FIG. 6b shows a detailed structure of a particle gathering element, according to the present invention;

FIG. 7a shows an upper section of an exhaust pipe separated from a lower section thereof, according to the present invention;

FIG. 7b shows particle removing devices of the invention;

FIGS. 8a to 8c show the operation of the low-pressure process apparatus, according to the present invention; and

FIG. 9 shows pneumatic devices and a supporting structure of the invention.

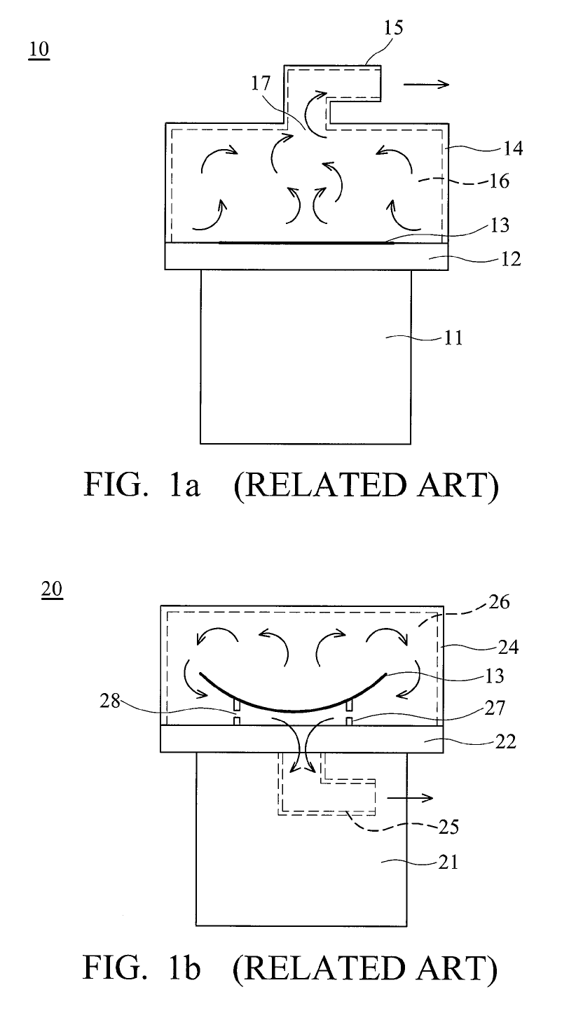

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

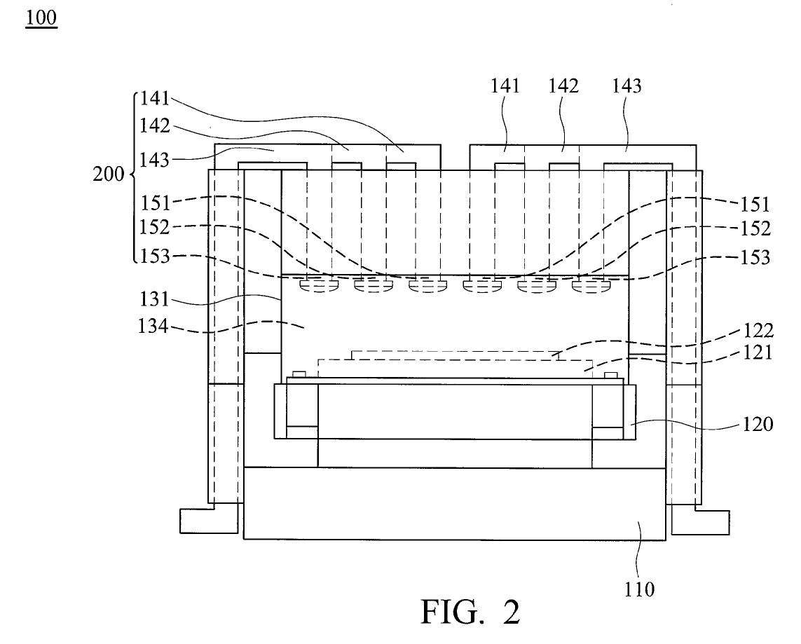

FIG. 2 is a front view of a low-pressure process apparatus 100 of the invention, comprising a base 110, a stage 120, a carrier 121, a housing 131 and an exhaust module 200. The exhaust module 200 comprises a first exhaust pipe 141, a second exhaust pipe 142, a third exhaust pipe 143, first exhaust openings 151, second exhaust openings 152 and third exhaust openings 153. The stage 120 is disposed on the base 110. The carrier 121 is disposed on the stage 120 to support a substrate 122. A chamber 134 is constructed of the housing 131 and the stage 120. The carrier 121 and the substrate 122 are located in the chamber 134. The first exhaust pipe 141, the second exhaust pipe 142 and the third exhaust pipe 143 extend into the chamber 134, and remove air therefrom through the first exhaust openings 151, the second exhaust openings 152 and the third exhaust openings 153, decreasing air pressure therein.

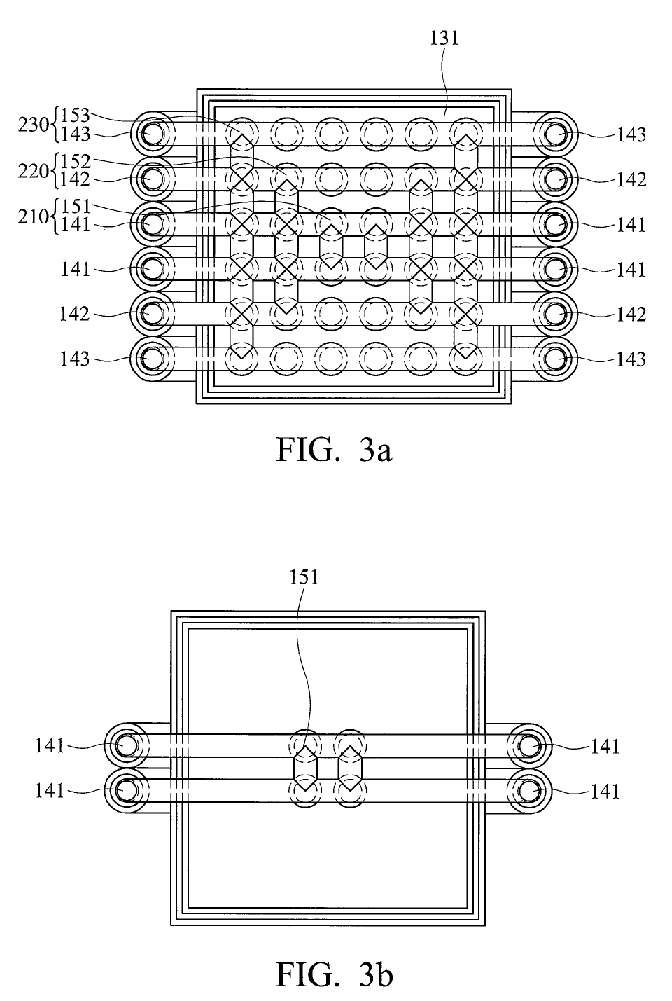

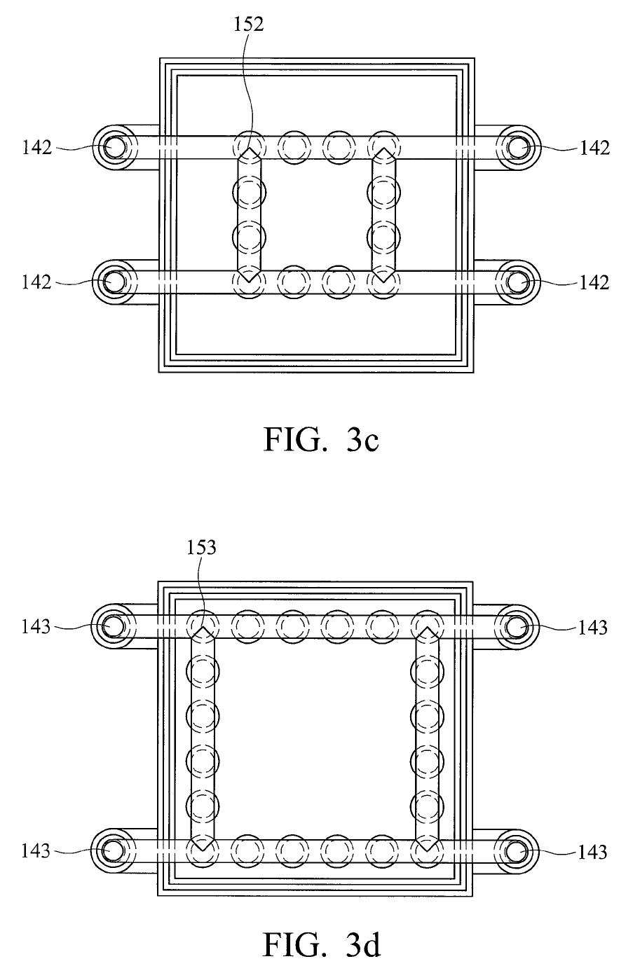

FIG. 3a is a top view of the low-pressure process apparatus 100, which shows a first exhaust unit 210 (comprising the first exhaust pipe 141 and the first exhaust openings 151), a second exhaust unit 220 (comprising the second exhaust pipe 142 and the second exhaust openings 152) and a third exhaust unit 230 (comprising the third exhaust pipe 143 and the third exhaust openings 153). The first exhaust openings 151 are in the center of the housing 131, the second exhaust opening 152 surrounds the first exhaust openings 151, and the third exhaust opening 153 surrounds the second exhaust opening 152. FIG. 3b shows the first exhaust pipe 141 and the first exhaust openings 151, FIG. 3c shows the second exhaust pipe 142 and the second exhaust openings 152, and FIG. 3d shows the third exhaust pipe 143 and the third exhaust openings 153. The first exhaust openings 151, the second exhaust openings 152 and the third exhaust openings 153 are arranged rectangularly in a matrix.

In one embodiment of the present invention, the first exhaust openings 151, the second exhaust openings 152 and the third exhaust openings 153 are arranged in concentric circles or other shapes.

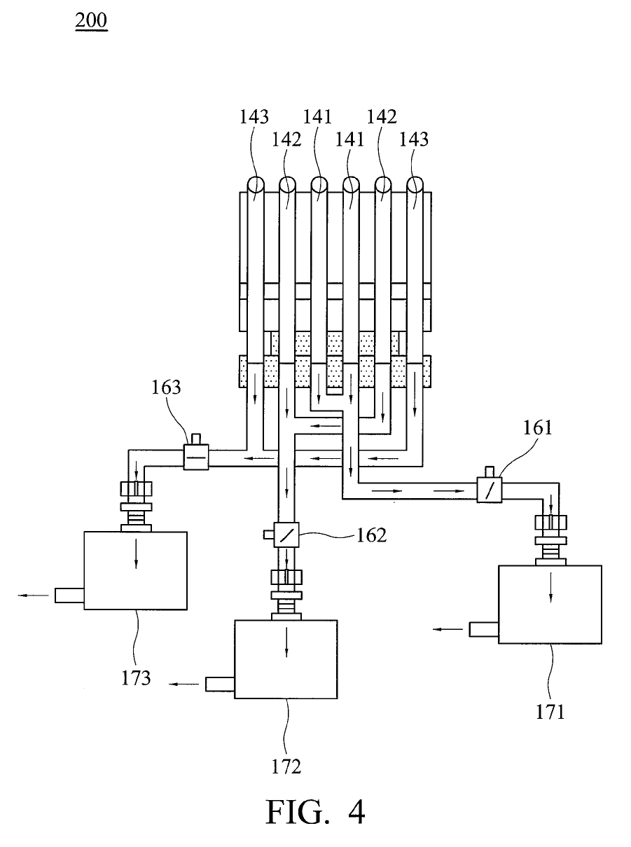

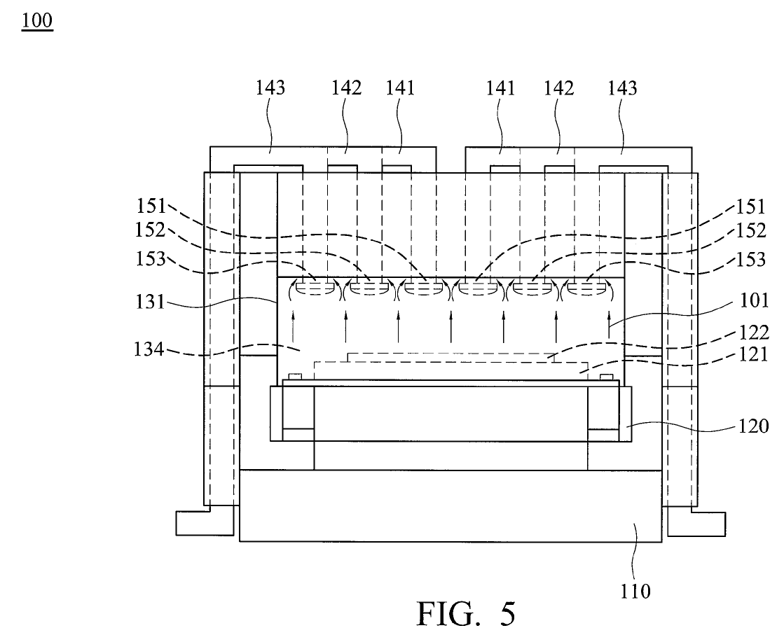

FIG. 4 is a side view of the low-pressure process apparatus 100, wherein the exhaust module 200 further comprises a first throttle 161, a first pressure reducer 171, a second throttle 162, a second pressure reducer 172, a third throttle 163 and a third pressure reducer 173. The first exhaust pipe 141 is connected to the first throttle 161 and the first pressure reducer 171. The second exhaust pipe 142 is connected to the second throttle 162 and the second pressure reducer 172. The third exhaust pipe 143 is connected to the third throttle 163 and the third pressure reducer 173. When the low-pressure process apparatus reduces the air pressure in the chamber, the fluid rate at the first throttle 161 is lower than the fluid rate at the second throttle 162, and the fluid rate at the second throttle 162 is lower than the fluid rate at the third throttle 163. Thus, the exhaust pressure at the first exhaust openings 151, the second exhaust openings 152 and the third exhaust openings 153 is substantially the same.

FIG. 5 shows the pressure reducing process of the low-pressure process apparatus 100. The first exhaust openings 151, the second exhaust openings 152 and the third exhaust openings 153 are arranged in a matrix. Air 101 in the chamber 134 is uniformly exhausted through the first exhaust openings 151, the second exhaust openings 152 and the third exhaust openings 153 in a vertical direction. Additionally, the exhaust pressure at the first exhaust openings 151, the second exhaust openings 152 and the third exhaust openings 153 is the same. Thus, air exhaust pressure in the chamber 134 is uniform, venting flow is prevented from generating, and the photoresist material on the substrate 122 is uniformly dried.

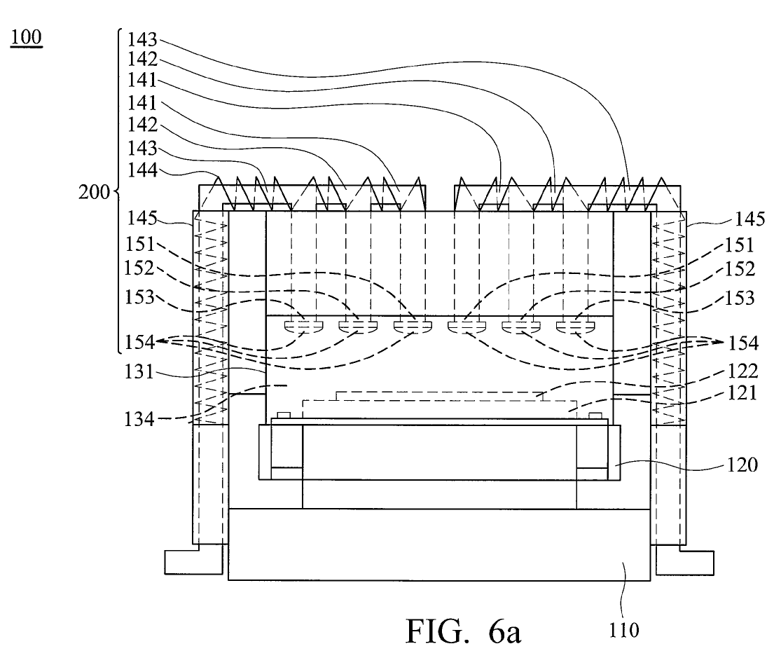

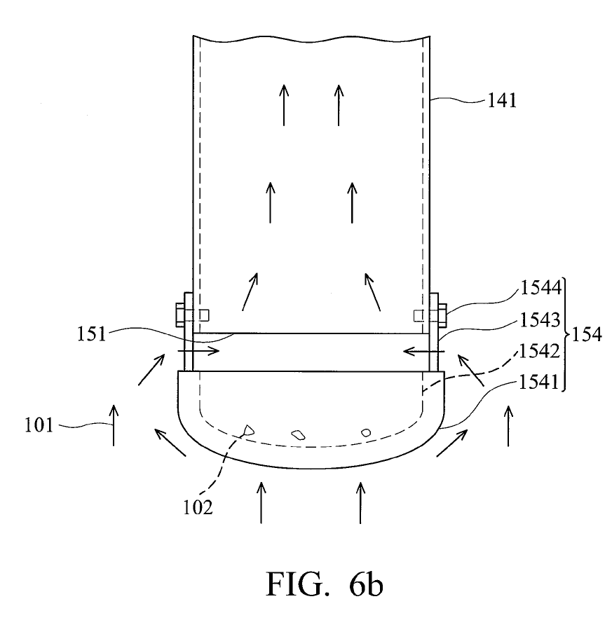

With reference to FIG. 6a, the exhaust module 200 further comprises particle gathering elements 154, a heater 144 and heat insulation material 145. The heater 144 is a heating wire, for example, surrounding the first exhaust pipe 141, the second exhaust pipe 142 and the third exhaust pipe 143. The heat insulation material 145 surrounds the first exhaust pipe 141, the second exhaust pipe 142, the third exhaust pipe 143 and the heater 144. The heater 144 heats the first exhaust pipe 141, the second exhaust pipe 142 and the third exhaust pipe 143 to 40° C. to 200° C. so as to prevent chemical material (for example, resin) from coagulating on the walls thereof. Thus, pollution in the first exhaust pipe 141, the second exhaust pipe 142 and the third exhaust pipe 143 is reduced. The particle gathering elements 154 are disposed below the first exhaust openings 151, the second exhaust openings 152 and the third exhaust openings 153 to prevent particles from entering the chamber 134. With reference to FIG. 6b, the particle gathering element 154 comprises a fluid guiding portion 1541, a concave 1542, a connection element 1543 and a fixer 1544. The particle gathering element 154 is disposed on the exhaust pipes (for example, first exhaust pipe 141) via the connection element 1543 and the fixer 1544. The fluid guiding portion 1541 is a curved surface opposite to the concave 1542 to guide air 101 and reduce venting flow. The concave 1542 corresponds to the exhaust openings (for example, first exhaust opening 151) and collects particles 102 dropped therefrom.

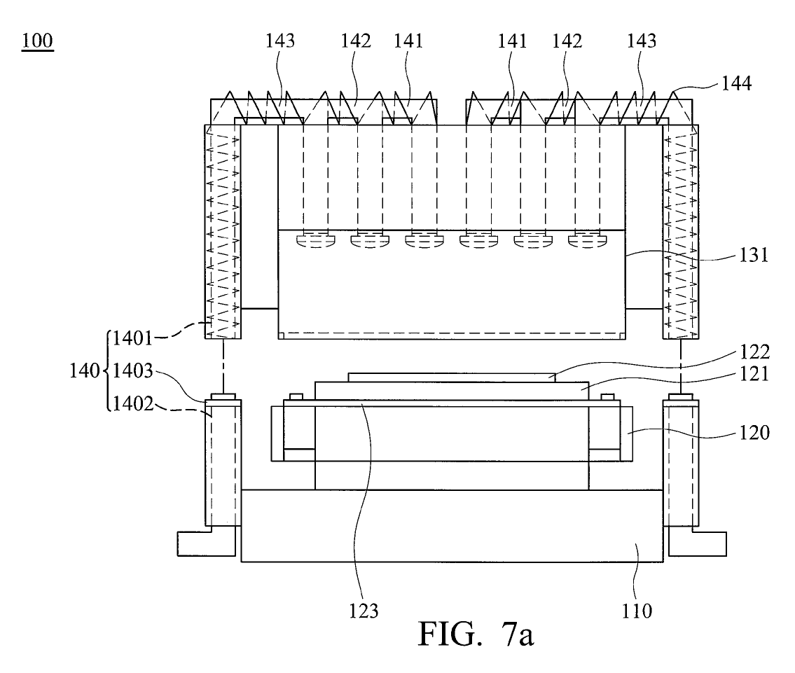

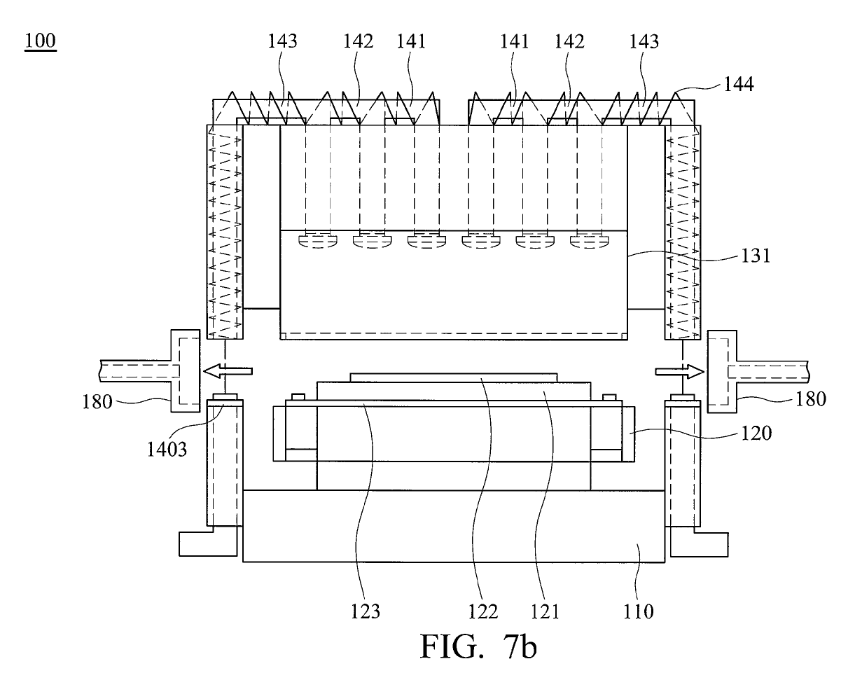

As shown in FIG. 7a, after the low-pressure process (for example, low pressure drying), the housing 131 raises, allowing a process tool (not shown) to access the substrate 122. First exhaust pipe 141, second exhaust pipe 142 and third exhaust pipe 143 comprise two sections. In FIG. 7a, for simplicity, the first exhaust pipe 141, the second exhaust pipe 142 and the third exhaust pipe 143 are represented by an exhaust pipe 140. The exhaust pipe 140 comprises an upper section 1401 and a lower section 1402. When the housing 131 raises, the upper section 1401 is separated from the lower section 1402. A non-return valve (not shown) is disposed in the upper section 1401 to prevent air in the upper section 1401 from flowing into the housing 131. Preferably, a rubber pad 1403 is disposed between the upper section 1401 and the lower section 1402, and a rubber pad 123 is disposed on the stage 120 to improve the seal.

With reference to FIG. 7b, in one embodiment of the present invention, the low-pressure process apparatus 100 further comprises particle removing devices 180 corresponding to a connection portion of the housing 131 and the base 120. The particle removing devices 180 remove particles from the housing 131 and the base 120 in a horizontal direction, particularly particles generated from the rubber pads 123 and 1403.

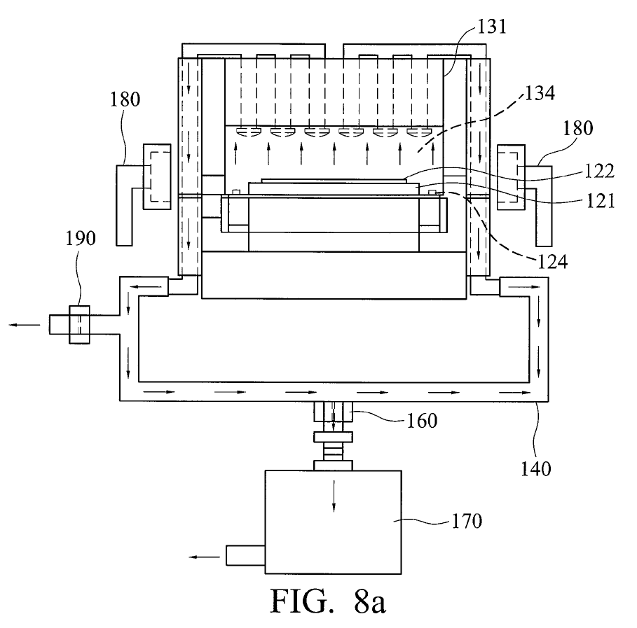

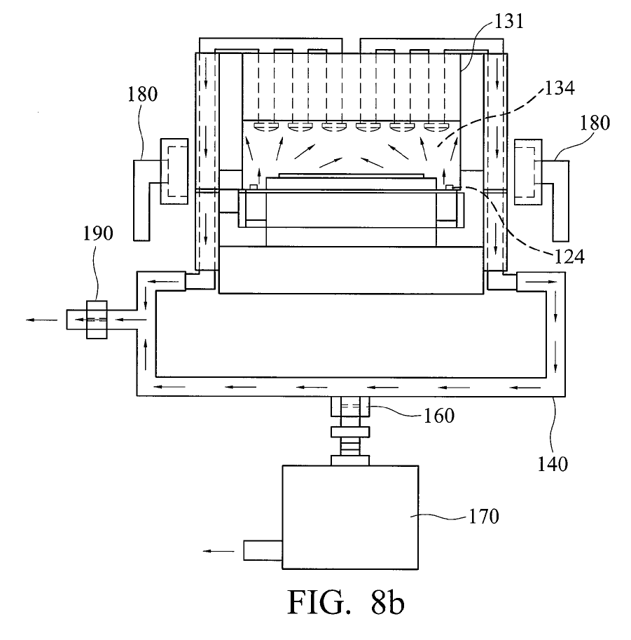

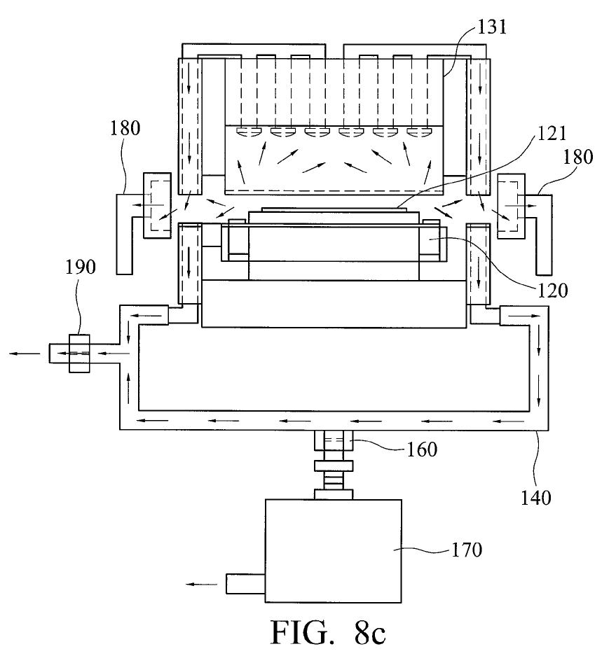

FIGS. 8a to 8c show operation of the low-pressure process apparatus 100. For simplicity, the exhaust pipe 140 represents the first exhaust pipe 141, the second exhaust pipe 142 and the third exhaust pipe 143, the throttle 160 represents the first throttle 161, the second throttle 162 and the third throttle 163, and the pressure reducer 170 represents the first pressure reducer 171, the second pressure reducer 172 and the third pressure reducer 173. With reference to FIG. 8a, during pressure reducing process, the housing 131 is in a first position, the throttle 160 opens, and the pressure reducer 170 removes air to reduce pressure in the chamber 134, wherein an exhaust valve 190 of the exhaust pipe 140 is closed. With reference to FIG. 8b, after the pressure reducing process, nozzles 124 inject nitrogen into the chamber 134, wherein the throttle 160 and the pressure reducer 170 are closed. The exhaust valve 190 opens to balance the pressure in the chamber 134 with ambient pressure, and prevent particles from being disturbed. Then, as shown in FIG. 8c, the housing 131 is separated from the stage 120 to a second position, wherein the particle removing devices 180 remove particles, the exhaust valve 190 is opening, and the throttle 160 and the pressure reducer 170 are closed. After the housing 131 moves to the second position, the substrate is accessed by a process tool (not shown).

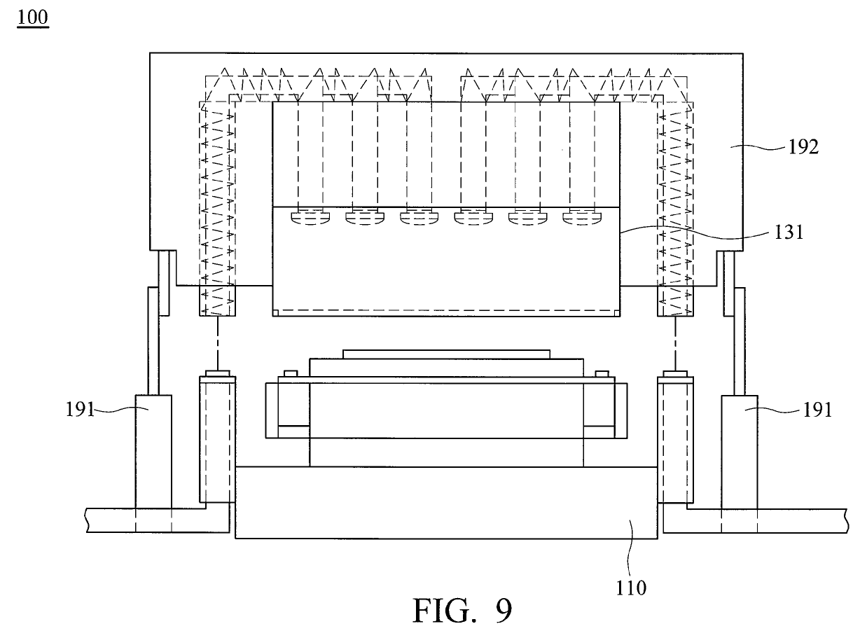

With reference to FIG. 9, the low-pressure process apparatus 100 further comprises pneumatic devices 191 and a supporting structure 192. The supporting structure 192 is disposed on the housing 131. The pneumatic devices 191 contact and support the supporting structure 192 to move the housing 131 between the first and second positions.

While the invention has been described by way of example and in terms of preferred embodiments, it is to be understood that the invention is not limited thereto. Rather, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A low-pressure process apparatus for processing a substrate, comprising:
a chamber;
a carrier, disposed in the chamber, for supporting the substrate; and
an exhaust module comprising a first exhaust unit and a second exhaust unit, the first exhaust unit comprising a plurality of first exhaust openings, the second exhaust unit comprising a plurality of second exhaust openings, the second exhaust openings surrounding the first exhaust openings, wherein the first and second exhaust openings are located in the chamber, and air in the chamber is exhausted through the first and second exhaust openings at substantially the same exhaust pressure.

2. The low-pressure process apparatus of claim 1, wherein the exhaust module is configured to remove the air from the chamber in a vertical direction.

3. The low-pressure process apparatus of claim 1, wherein the first and the second exhaust openings are arranged in a matrix.

4. The low-pressure process apparatus of claim 1, wherein the exhaust module further comprises at least one exhaust pipe for communicating with the first and second exhaust openings.

5. The low-pressure process apparatus of claim 1, wherein the exhaust pipe extends out of the chamber.

6. The low-pressure process apparatus of claim 5, wherein the exhaust module further comprises at least one heater for heating the exhaust pipe.

7. The low-pressure process apparatus of claim 6, wherein the at least one heater comprising a heating wire surrounding the exhaust pipe.

8. The low-pressure process apparatus of claim 7, wherein the exhaust module further comprises at least one heat insulation material surrounding the exhaust pipe and the heater.

9. The low-pressure process apparatus of claim 1, wherein the first exhaust unit further comprises at least one first exhaust pipe, the second exhaust unit further comprises at least one second exhaust pipe, the first exhaust pipe is communicating with the first exhaust opening, and the second exhaust pipe is communicating with the second exhaust opening.

10. The low-pressure process apparatus of claim 1, wherein the exhaust module further comprises a plurality of particle gathering elements, and each particle gathering element is disposed below the first or second exhaust opening.

11. The low-pressure process apparatus of claim 10, wherein each particle gathering element comprises a concave corresponding to the first or second exhaust opening.

12. The low-pressure process apparatus of claim 11, wherein each particle gathering element further comprises a fluid guiding portion opposite to the concave, and the fluid guiding portion has a curved surface.

13. A low-pressure process apparatus for processing a substrate, comprising:
a stage;
a carrier, disposed on the stage, for supporting the substrate;
a housing disposed detachably on the stage and moveably between a first position and a second position, wherein when the housing is in the first position, the housing and the stage compose a chamber, and the carrier is located in the chamber; and
an exhaust module comprising a plurality of exhaust openings disposed above the carrier, wherein air in the chamber is exhausted through the exhaust openings so as to decrease air pressure therein.

14. The low-pressure process apparatus of claim 13, wherein the exhaust module is configured to remove the air from the chamber in a vertical direction.

15. The low-pressure process apparatus of claim 14, further comprising a particle removing device corresponding to a connection position of the housing and the stage, wherein when the housing moves from the first position to the second position, the particle removing device removes particles therefrom.

16. The low-pressure process apparatus of claim 14, wherein the particle removing device is configured to draw the air in a horizontal direction to remove the particles.

17. A low-pressure process apparatus for processing a substrate, comprising:
a chamber;
a carrier, disposed in the chamber, for supporting the substrate; and
an exhaust module comprising a plurality of exhaust openings and a plurality of particle gathering elements, the exhaust openings being located in the chamber above the carrier, wherein air in the chamber is exhausted through the exhaust openings so as to decrease air pressure therein, and each particle gathering element is disposed below each exhaust opening.

18. The low-pressure process apparatus of claim 17, wherein each particle gathering element comprises a concave corresponding to the exhaust opening.

19. The low-pressure process apparatus of claim 18, wherein each particle gathering element further comprises a fluid guiding portion opposite to the concave, and the fluid guiding portion has a curved surface.
